(19) United States
(12) Patent Application Publication
(10) Pub. No.: US 2023/0400776 A1
(43) Pub. Date: Dec. 14, 2023

(54) Multi Pattern Maskless Lithography Method and System

(71) Applicant: Orbotech Ltd., Yavne (IL)

(72) Inventor: Uri Gold, Rishon Le Zion (IL)

(21) Appl. No.: 18/035,283

(22) PCT Filed: Jun. 20, 2021
(86) PCT No.: PCT/IL2021/050746

§ 371 Date: May 3, 2023

Related U.S. Application Data
(60) Provisional application No. 63/114,541, filed on Nov. 17, 2020.
(60) Provisional application No. 63/193,564, filed on May 26, 2021.

(51) Int. Cl. G03F 7/00; G03F 7/20

(52) U.S. Cl. CPC G03F 7/70383; G03F 7/2051

(57) ABSTRACT

Maskless lithography apparatus including a chassis supporting a substrate onto which it is desired to write, an optical writing head, the optical writing head operating at at least one of a plurality of at least partially different wavelength/intensity ranges, a displacement subsystem for providing desired relative displacement between the substrate and the optical writing head and a writing controller operative to cause the optical writing head to sequentially write a plurality of different patterns at correspondingly different ones of the at least one of a plurality of at least partially different wavelength/intensity ranges.

### FIELD OF THE DISCLOSURE

The present invention relates to maskless lithography apparatus and methodology, which is particularly useful in the electronics industry.

### BACKGROUND OF THE DISCLOSURE

Various types of maskless lithography equipment and methods are known in the patent literature and in the market.

### SUMMARY OF THE DISCLOSURE

The present invention seeks to provide improved maskless lithography apparatus and methodology.

More specifically, the present invention seeks to provide a method and apparatus for maskless lithography in which an optical writing head, is selectably operable at either or both of multiple wavelength ranges and at multiple intensity ranges to sequentially write a plurality of different patterns at correspondingly different wavelength ranges, at correspondingly different intensity ranges or at correspondingly different combinations of wavelength ranges and intensity ranges. For simplicity, throughout the specification and the drawings, different wavelength ranges, different intensity ranges and different combinations of wavelength ranges and intensity ranges are referred to collectively as “wavelength/intensity” or “W/I”.

There is thus provided in accordance with an embodiment of the present invention maskless lithography apparatus including a chassis supporting a substrate onto which it is desired to write, an optical writing head, the optical writing head being selectably operable at multiple ones of at least one of a plurality of at least partially different wavelength ranges and a plurality of at least partially different intensity ranges, a displacement subsystem for providing desired relative displacement between the substrate and the optical writing head and a writing controller operative to cause the optical writing head to sequentially write a plurality of different patterns at correspondingly different ones of the multiple ones of at least one of a plurality of at least partially different wavelength ranges and a plurality of at least partially different intensity ranges.

The writing controller can be operative to cause the optical writing head to sequentially write each of the different patterns at correspondingly at least partially different wavelength ranges by writing mutually partially overlapping spots of different spot sizes for each of the different patterns using light at correspondingly different ones of the at least partially different wavelength ranges.

Alternatively, the writing controller is operative to cause the optical writing head to sequentially write each of the different patterns at correspondingly at least partially different intensity ranges by writing mutually partially overlapping spots of different spot sizes for each of the different patterns using light at correspondingly different ones of the at least partially different intensity ranges.

In accordance with an embodiment of the present invention the writing controller is operative to cause the optical writing head to sequentially write each of the different patterns at correspondingly at least partially different wavelength/intensity ranges by writing mutually partially overlapping spots of different spot sizes for each of the different patterns using light at correspondingly different ones of the at least partially different wavelength/intensity ranges.

The mutually partially overlapping spots of different spot sizes can be non-concentric.

In accordance with an embodiment of the present invention at least one of the different patterns defines an alphanumeric character. Additionally or alternatively, the writing controller is also operative to cause the optical writing head to write legends on soldermask.

In accordance with an embodiment of the present invention the writing controller is operative to cause the optical writing head to write each of the different patterns in a plurality of frames at a corresponding plurality of different times. Additionally, the writing controller is operative to write each of the plurality of different patterns with a plurality of spots of a uniform size, the uniform size of the spots for each of the plurality of different patterns being different.

The plurality of spots written for each of the different patterns can be written at partially mutually overlapping locations on the substrate.

In accordance with an embodiment of the present invention the plurality of spots written for each of the different patterns are each written at locations such that the centers of all of spots forming a single pattern lie inside a single spot center outline. Additionally, the spot center outline of each pattern is arranged such that the spot does not extend beyond the design boundaries of an object to be written thereby.

There is also provided in accordance with another embodiment of the present invention maskless lithography apparatus including a chassis supporting a substrate onto which it is desired to write, an optical writing head, the optical writing head being selectably operable at multiple ones of at least one of a plurality of at least partially different wavelength ranges, a displacement subsystem for providing desired relative displacement between the substrate and the optical writing head and a plurality of at least partially different intensity ranges and a writing controller operative to cause the optical writing head to write a plurality of different patterns at corresponding ones of the plurality of at least partially different wavelength ranges by writing partially mutually overlapping non-concentric spots at correspondingly different ones of the multiple ones of at least one of a plurality of at least partially different wavelength ranges and a plurality of at least partially different intensity ranges.

At least one of the different patterns can define an alphanumeric character. Additionally or alternatively, the writing controller is also operative to cause the optical writing head to write legends on soldermask.

In accordance with an embodiment of the present invention the writing controller is operative to cause the optical writing head to write each of the different patterns in a plurality of frames at a corresponding plurality of different times. Additionally, the writing controller is operative to write each of the plurality of different patterns with a plurality of spots of a uniform size, the uniform size of the spots for each of the plurality of different patterns being different.

The plurality of spots written for each of the different patterns can be written at partially mutually overlapping locations on the substrate.

In accordance with an embodiment of the present invention the plurality of spots written for each of the different patterns are each written at locations such that the centers of all of spots forming a single pattern lie along a single spot center outline. Additionally, the spot center outline of each pattern is arranged such that the spot does not extend beyond the design boundaries of an object to be written thereby.

There is further provided in accordance with yet another embodiment of the present invention maskless lithography apparatus including a chassis supporting a substrate onto which it is desired to write, an optical writing head, the optical writing heads being selectably operable at multiple ones of a plurality of at least partially different wavelength ranges, a displacement subsystem for providing desired relative displacement between the substrate and the optical writing head and a writing controller operative to cause the optical writing head to sequentially write a plurality of different patterns at corresponding ones of the plurality of at least partially different wavelength ranges, the plurality of different patterns including patterns for electrical circuit features and alphanumeric characters.

The writing controller can be operative to cause the optical writing head to sequentially write each of the different patterns at correspondingly at least partially different wavelength ranges by writing mutually partially overlapping spots of different spot sizes for each of the different patterns using light at correspondingly different ones at least partially different wavelength ranges. Additionally, the mutually partially overlapping spots of different spot sizes are non-concentric.

In accordance with an embodiment of the present invention the writing controller is also operative to cause the optical writing head to write legends on soldermask. Additionally or alternatively, the writing controller is operative to cause the optical writing head to write each of the different patterns in a plurality of frames at a corresponding plurality of different times.

In accordance with an embodiment of the present invention the writing controller is operative to write each of the plurality of different patterns with a plurality of spots of a uniform size, the uniform size of the spots for each of the plurality of different patterns being different. Additionally, the plurality of spots written for each of the different patterns are written at partially mutually overlapping locations on the substrate.

The plurality of spots written for each of the different patterns can be each written at locations such that the centers of all of spots forming a single pattern lie along a single spot center outline. Additionally, the spot center outline of each pattern is arranged such that the spot does not extend beyond the design boundaries of an object to be written thereby.

In accordance with an embodiment of the present invention the optical writing head operates at a plurality of at least partially different wavelength ranges and the writing controller is operative to cause the optical writing head to sequentially write a plurality of different patterns at correspondingly different ones of the plurality of at least partially different wavelength ranges. Additionally or alternatively, the optical writing head operates at a plurality of at least partially different intensity ranges and the writing controller is operative to cause the optical writing head to sequentially write a plurality of different patterns at correspondingly different ones of the plurality of at least partially different intensity ranges.

The optical writing head can operate at a plurality of at least partially different wavelength ranges and at a plurality of at least partially different intensity ranges and the writing controller is operative to cause the optical writing head to sequentially write a plurality of different patterns at correspondingly different ones of the plurality of at least partially different wavelength ranges and at a plurality of at least partially different intensity ranges.

In accordance with an embodiment of the present invention the optical writing head is capable of writing with a legend and text resolution of less than 300 microns. The optical writing head can be capable of writing with a legend and text resolution of less than 200 microns. In an instance, the optical writing head is capable of writing with a legend and text resolution of less than 100 microns. In another instance, the optical writing head is capable of writing with a legend and text resolution of less than 50 micron.

In accordance with an embodiment of the present invention the writing controller is operative to cause the optical writing head to sequentially write a plurality of different patterns in a selectable sequence.

The writing controller can be operative to cause the optical writing head to sequentially write a plurality of different patterns at different intensities.

In accordance with an embodiment of the present invention the writing controller is operative to cause the optical writing head to write a pattern at a size, intensity and soldermask legend hue which is invisible to the unaided human eye. Additionally or alternatively, the writing controller is operative to cause the optical writing head to write a legend at a size, intensity and soldermask legend hue which is invisible to the unaided human eye.

In accordance with an embodiment of the present invention the writing controller is operative to cause the optical writing head to write a legend with a legend to soldermask accuracy of less than 5 microns. In an instance, the writing controller is operative to cause the optical writing head to write a legend with a legend to soldermask accuracy of less than one micron. In another instance, the writing controller is operative to cause the optical writing head to write a legend with a legend to soldermask accuracy of less than 0.5 micron. In another instance, the writing controller is operative to cause the optical writing head to write a legend with a legend to soldermask accuracy of less than 0.1 micron.

In accordance with an embodiment of the present invention the writing controller is operative to cause the optical writing head to write a legend at a spot size of less than 30 microns. In an instance, the writing controller is operative to cause the optical writing head to write a legend at a spot size of less than 20 microns. In another instance, the writing controller is operative to cause the optical writing head to write a legend at a spot size of less than 10 microns. In another instance, the writing controller is operative to cause the optical writing head to write a legend at a spot size of less than 5 microns.

There is even further provided in accordance with still another embodiment of the present invention a method for maskless lithography, the method including providing an optical writing head, the optical writing head being selectably operable at multiple ones of at least one of a plurality of at least partially different wavelength ranges and a plurality of at least partially different intensity ranges and sequentially writing, onto a substrate, a plurality of different patterns at correspondingly different ones of the multiple ones of at least one of a plurality of at least partially different wavelength ranges and a plurality of at least partially different intensity ranges.

The method also can include providing a desired relative displacement between the substrate and the optical writing head.

In accordance with an embodiment of the present invention the sequentially writing includes sequentially writing each of the different patterns at correspondingly at least partially different wavelength ranges by writing mutually partially overlapping spots of different spot sizes for each of the different patterns using light at correspondingly different ones of the at least partially different wavelength ranges.

Alternatively, the sequentially writing comprises sequentially writing each of the different patterns at correspondingly at least partially different intensity ranges by writing mutually partially overlapping spots of different spot sizes for each of the different patterns using light at correspondingly different ones of the at least partially different intensity ranges.

In accordance with an embodiment of the present invention the sequentially writing comprises sequentially writing each of the different patterns at correspondingly at least partially different wavelength/intensity ranges by writing mutually partially overlapping spots of different spot sizes for each of the different patterns using light at correspondingly different ones of the at least partially different wavelength/intensity ranges.

The mutually partially overlapping spots of different spot sizes can be non-concentric.

At least one of the different patterns can define an alphanumeric character. Additionally or alternatively, the sequentially writing includes writing one or more legends on soldermask.

In accordance with an embodiment of the present invention the sequentially writing includes writing each of the different patterns in a plurality of frames at a corresponding plurality of different times. Additionally, the sequentially writing includes writing each of the plurality of different patterns with a plurality of spots of a uniform size, the uniform size of the spots for each of the plurality of different patterns being different.

In accordance with an embodiment of the present invention the sequentially writing also includes writing the plurality of spots for each of the different patterns at partially mutually overlapping locations on the substrate.

The sequentially writing also can include writing the plurality of spots for each of the different patterns at locations such that the centers of all of spots forming a single pattern lie inside a single spot center outline. Additionally, the method also includes arranging the spot center outline of each pattern such that the spot does not extend beyond the design boundaries of an object to be written thereby.

There is also provided in accordance with another embodiment of the present invention a method for maskless lithography, the method including providing an optical writing head, the optical writing head being selectably operable at multiple ones of at least one of a plurality of at least partially different wavelength ranges and a plurality of at least partially different intensity ranges and sequentially writing, onto a substrate, a plurality of different patterns at corresponding ones of the plurality of at least partially different wavelength ranges by writing partially mutually overlapping non-concentric spots at correspondingly different ones of the multiple ones of at least one of a plurality of at least partially different wavelength ranges and a plurality of at least partially different intensity ranges.

The method also can include providing a desired relative displacement between the substrate and the optical writing head.

In accordance with an embodiment of the present invention at least one of the different patterns defines an alphanumeric character. Additionally or alternatively, the sequentially writing includes writing one or more legends on soldermask.

The sequentially writing can include writing each of the different patterns in a plurality of frames at a corresponding plurality of different times. Additionally, the sequentially writing includes writing each of the plurality of different patterns with a plurality of spots of a uniform size, the uniform size of the spots for each of the plurality of different patterns being different.

In accordance with an embodiment of the present invention the sequentially writing includes writing the plurality of spots for each of the different patterns at partially mutually overlapping locations on the substrate.

The sequentially writing can include writing the plurality of spots for each of the different patterns at locations such that the centers of all of spots forming a single pattern lie along a single spot center outline. Additionally, the method also includes arranging the spot center outline of each pattern such that the spot does not extend beyond the design boundaries of an object to be written thereby.

There is still further provided in accordance with yet another embodiment of the present invention a method for maskless lithography, the method including providing an optical writing head, the optical writing head being selectably operable at a plurality of at least partially different wavelength ranges and sequentially writing, onto a substrate, a plurality of different patterns at correspondingly ones at least one of the plurality of at least partially different wavelength ranges, the plurality of patterns including patterns for electrical circuit features and alphanumeric characters.

The method also can include providing a desired relative displacement between the substrate and the optical writing head.

In accordance with an embodiment of the present invention the sequentially writing includes sequentially writing mutually partially overlapping spots of different spot sizes for each of the different patterns using light at correspondingly different ones at least partially different wavelength ranges. Additionally, the mutually partially overlapping spots of different spot sizes are non-concentric.

In accordance with an embodiment of the present invention the sequentially writing includes writing one or more legends on soldermask. Additionally or alternatively, the sequentially writing includes writing each of the different patterns in a plurality of frames at a corresponding plurality of different times.

The sequentially writing can include writing each of the plurality of different patterns with a plurality of spots of a uniform size, the uniform size of the spots for each of the plurality of different patterns being different. In accordance with an embodiment of the present invention the sequentially writing includes writing the plurality of spots for each of the different patterns at partially mutually overlapping locations on the substrate.

In accordance with an embodiment of the present invention the sequentially writing includes writing the plurality of spots for each of the different patterns at locations such that the centers of all of spots forming a single pattern lie along a single spot center outline. Additionally, the method also includes arranging the spot center outline of each pattern such that the spot does not extend beyond the design boundaries of an object to be written thereby.

The sequentially writing can include sequentially writing the plurality of different patterns at correspondingly different ones of the plurality of at least partially different wavelength ranges. Additionally or alternatively, the sequentially writing includes sequentially writing the plurality of different patterns at correspondingly different ones of the plurality of at least partially different intensity ranges. In accordance with an embodiment of the present invention the sequentially writing includes sequentially writing the plurality of different patterns at correspondingly different ones of the plurality of at least partially different wavelength ranges and at a plurality of at least partially different intensity ranges.

In accordance with an embodiment of the present invention the sequentially writing includes writing with a legend and text resolution of less than 300 microns. In an instance, the sequentially writing includes writing with a legend and text resolution of less than 200 microns. In another instance, the sequentially writing includes writing with a legend and text resolution of less than 100 microns. In another instance, the sequentially writing includes writing with a legend and text resolution of less than 50 microns.

In accordance with an embodiment of the present invention the sequentially writing includes sequentially writing a plurality of different patterns in a selectable sequence.

In accordance with an embodiment of the present invention the sequentially writing includes sequentially writing a plurality of different patterns at different intensities. The sequentially writing can include writing a pattern at a size, intensity and soldermask legend hue which is invisible to the unaided human eye. Additionally or alternatively, the sequentially writing includes writing a legend at a size, intensity and soldermask legend hue which is invisible to the unaided human eye.

In accordance with an embodiment of the present invention, the sequentially writing includes sequentially writing a legend with a legend to soldermask accuracy of less than 5 microns. In an instance, the sequentially writing includes sequentially writing a legend with a legend to soldermask accuracy of less than one micron. In another instance, the sequentially writing includes sequentially writing a legend with a legend to soldermask accuracy of less than 0.5 micron. In another instance, the sequentially writing includes sequentially writing a legend with a legend to soldermask accuracy of less than 0.1 micron.

The sequentially writing can include sequentially writing a legend at a spot size of less than 30 microns. In an instance, the sequentially writing includes sequentially writing a legend at a spot size of less than 20 microns. In another instance, the sequentially writing includes sequentially writing a legend at a spot size of less than 10 microns. In another instance, the sequentially writing includes sequentially writing a legend at a spot size of less than 5 microns.

### BRIEF DESCRIPTION OF THE DRAWINGS

FIG. 1 is a simplified illustration of maskless lithography apparatus constructed and operative in accordance with an embodiment of the present invention;

FIG. 2 is a simplified illustration of an optical writing assembly forming part of the maskless lithography apparatus of FIG. 1;

FIG. 3A is a simplified illustration of writing a typical object with light at multiple wavelengths/intensities in accordance with the teachings of the prior art;

FIG. 3B is a simplified illustration of writing the object of FIG. 3A with light at multiple wavelengths/intensities in accordance with an embodiment of the present invention;

FIG. 3C is a simplified illustration of writing the object of FIGS. 3A and 3B and a legend with light at multiple wavelengths/intensities in accordance with an embodiment of the present invention;

FIGS. 4A, 4B, 4C, 4D, 4E, 4F and 4G are simplified schematic illustrations of direct writing of multiple frames of three different patterns, using a different wavelength/intensity for each pattern in accordance with an embodiment of the present invention; and

FIG. 5 is a simplified schematic timing and displacement diagram illustrating typical writing operation of an optical writing head, sequentially writing frames of three different patterns, using a different wavelength/intensity for each pattern, onto a moving substrate in accordance with an embodiment of the present invention.

### DETAILED DESCRIPTION OF THE DISCLOSURE

The present invention provides a method and apparatus for maskless lithography in which an optical writing head, can be selectably operable at either or both of multiple wavelength ranges and at multiple intensity ranges to sequentially write a plurality of different patterns at correspondingly different wavelength ranges, at correspondingly different intensity ranges or at correspondingly different combinations of wavelength ranges and intensity ranges. For simplicity, throughout the specification and the drawings, different wavelength ranges, different intensity ranges and different combinations of wavelength ranges and intensity ranges are referred to collectively as “wavelength/intensity” or “W/I”.

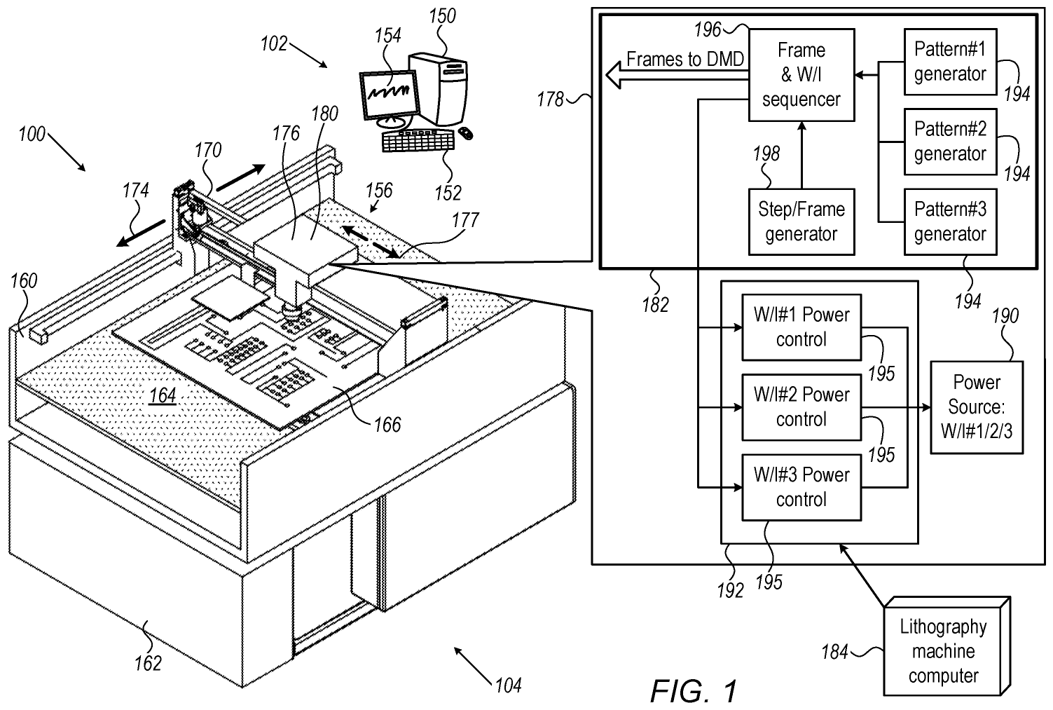

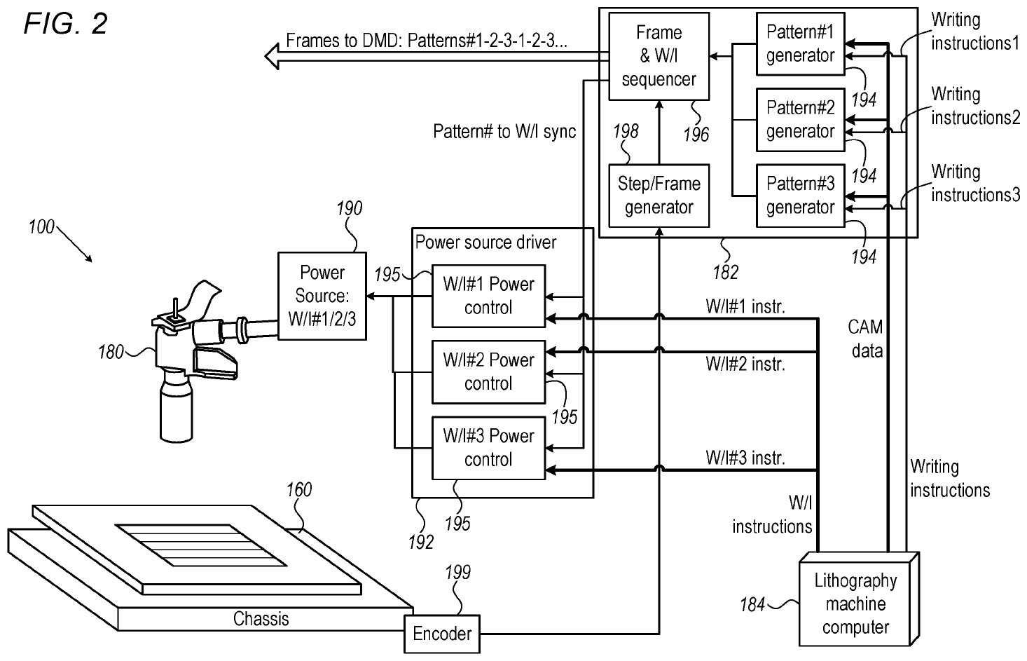

Reference is now made to FIG. 1 and FIG. 2, which are simplified illustrations of maskless lithography apparatus 100 constructed and operative in accordance with an embodiment of the present invention. As seen in FIG. 1, the maskless lithography apparatus can be based on a chassis of a conventional direct writing machine, such as an Orbotech Diamond™ machine, commercially available from Orbotech Ltd.

As seen in FIG. 1, the apparatus can include a workstation 102 and a direct writing subsystem 104. Workstation 102 can include a computer 150, a user input interface 152 and a display 154.

Direct writing subsystem 104 can comprise a substrate positioning assembly 156 including a chassis 160, which can be mounted on a conventional optical table 162. The chassis 160 defines a support 164 onto which a substrate 166 to be written upon, typically the precursor of an electrical circuit, such as a printed circuit board (PCB), a flexible printed circuit (FPC), electrical circuit artwork, a flat panel display (FPD) or a wafer, may be placed.

Substrate positioning assembly 156 also can include a bridge 170, arranged for linear motion relative to support 164, typically along a first axis 174 defined with respect to chassis 160. Alternatively, bridge 170 may be fixed and the substrate 166 may be displaced relative thereto, such as in roll-to-roll processing. As a further alternative, bridge 170 may be fixed and substrate 166 may be displaced relative thereto with suitable single or multiple axis motion.

Subsystem 104 also can comprise an optical writing assembly 176, which can be arranged for linear motion relative to bridge 170 along a second axis 177, perpendicular to first axis 174. Alternatively, the optical writing assembly 176 may be a stationary optical assembly and chassis 160 may provide X and/or Y movement of substrate 166 relative to optical writing assembly 176. The optical writing assembly 176 includes an optical writing controller 178.

In accordance with an embodiment of the present invention, the optical writing controller 178 comprises one or more optical writing heads 180, each of which may include a digital micromirror device (DMD). An optical writing head 180 is the writing head of an Orbotech-DIAMOND-8 machine, described at https://www.orbotech.com/assets/media/orbotech-diamond-8-brochure-for-web.pdf, which is commercially available from Orbotech Ltd. of Yavne, Israel. The optical writing controller 178 also can include an image processing unit 182, which receives CAM data from a lithography computer 184 and provides frame writing instructions to the one or more optical writing heads 180. The optical writing controller 178 also can comprise a multiple wavelength/intensity (W/I) power source 190 which receives control inputs from a power source driver 192, which in turn receives writing instructions from lithography computer 184.

As seen particularly in FIG. 2, the lithography computer 184 can provide CAD/CAM image data and pattern writing instructions to a plurality of pattern generators 194, forming part of image processing unit 182. The lithography computer 184 also provides wavelength/intensity writing instructions to multiple wavelength/intensity (W/I) power controllers 195 in power source driver 192. As used throughout, the term “pattern” refers to the arrangement of a plurality of exposed spots which are all written with light of the same wavelength/intensity (W/I). A pattern typically extends over an entire CAD/CAM image.

The computer 150 and/or lithography computer 184 can include a personal computer system, image computer, mainframe computer system, workstation, network appliance, internet appliance, or other device. In some embodiments, various steps, functions, and/or operations of the systems, sub-systems, and methods disclosed herein are carried out by one or more of the following: electronic circuits, logic gates, multiplexers, programmable logic devices, ASICs, analog or digital controls/switches, microcontrollers, or computing systems. Program instructions implementing methods such as those described herein may be transmitted over or stored on carrier medium. The carrier medium may include a storage medium such as a read-only memory, a random access memory, a magnetic or optical disk, a non-volatile memory, a solid state memory, a magnetic tape, and the like. A carrier medium may include a transmission medium such as a wire, cable, or wireless transmission link. For instance, the various steps described throughout the present disclosure may be carried out by a single processor (or computer system) or, alternatively, multiple process (or multiple computer systems).

The pattern generators 194 can supply image data to a frame and wavelength/intensity (W/I) sequencer 196, which in turn receives sequence inputs from a step/frame generator 198, which receives substrate position information from an encoder 199 coupled to chassis 160.

Frame and wavelength/intensity (W/I) sequencer 196 can output pattern writing data to the DMD of each of the one or more optical writing heads 180. Each of multiple wavelength/intensity (W/I) power controllers 195 in power source driver 192 receives wavelength/intensity (W/I) selection outputs from sequencer 196 and provides a wavelength/intensity (W/I) selection output to power source 190. Power source 190 can provide a power output, based on each wavelength/intensity (W/I) of the wavelength/intensity (W/I) selected to be written, to the one or more optical writing heads 180.

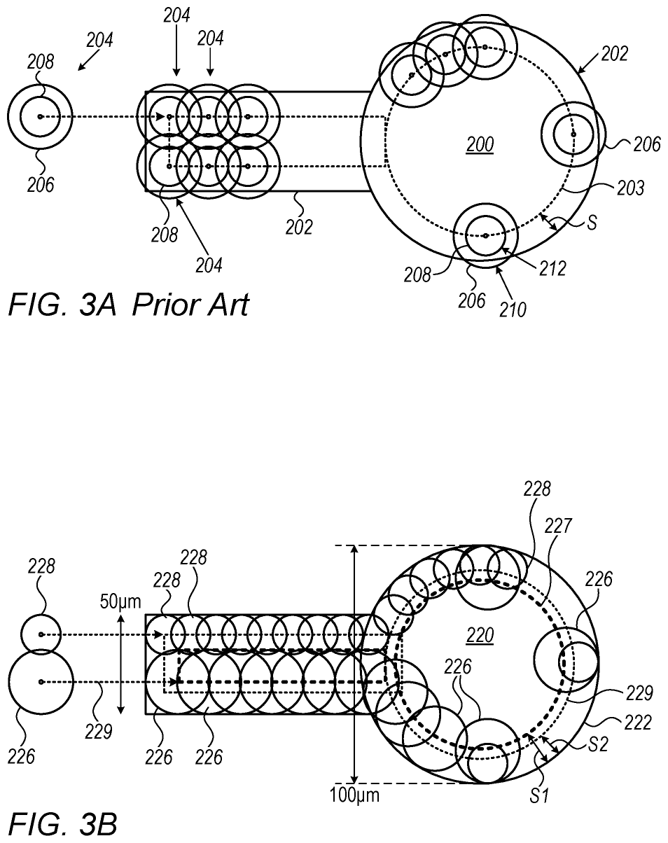

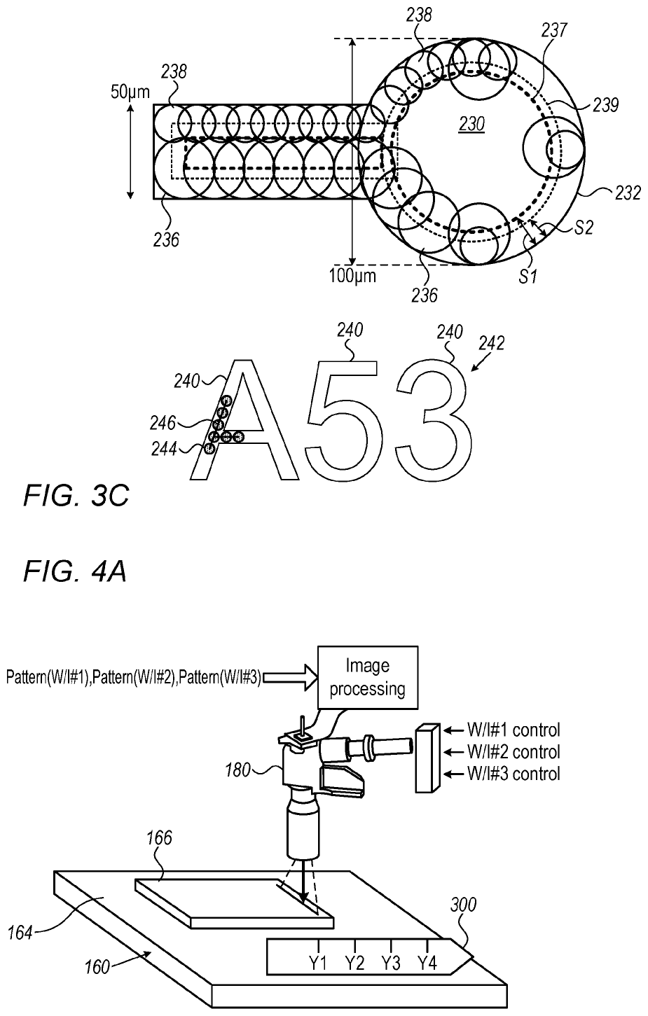

Reference is now made to FIG. 3A, which illustrates direct writing in accordance with the prior art wherein the desired dimensions of an object to be written, such as a pad 200, as dictated by CAM data, are indicated by an outline designated by reference numeral 202. Due to requirements and constraints of conventional lithography, the object, such as pad 200, is written in a collection of spots with light at multiple selected wavelengths/intensities. In accordance with the prior art and as shown in FIG. 3A, the centers of all of the spots, written with light at all of the multiple selected wavelengths/intensities, lie along a single spot center outline 203, which is normally interior of and spaced from the outline 202 by a separation S.

Reference numeral 204 designates a typical composite spot including first and second mutually concentric spots 206 and 208, which are simultaneously written using light at first and second wavelengths. In the illustrated example, the first wavelength is 365 nm, the intensity is between 1 W and 20 W per frame, the spot size of spot 206, as measured by the diameter of spot 206, is 30 microns, the second wavelength is 385 nm, the intensity is between 1 W and 20 W per frame and the spot size of spot 208, as measured by the diameter of spot 208, is 20 microns. The object, here pad 200, is written by exposing a multiplicity of partially overlapping composite spots 204. Typically an object, such as a pad, having a maximum dimension ranging from approximately 30 microns to several millimeters, is written by exposing hundreds of thousands of mutually overlapping composite spots 204, wherein adjacent composite spots have a degree of overlap of at least 10%-50%. It is appreciated that for the sake of clarity of the drawings, in FIGS. 3A-3C only a few representative composite spots 204 are shown and thus the illustrated extent of overlap between the illustrated composite spots 204 is much less than approximately 50%.

Due to the variability of the point spread function (PSF) as a function of wavelength and intensity, and due to the prior art constraint that all of the spots in each composite spot 204 be concentric, it is seen that the location of center outline 203 and its separation S from outline 202 is a compromise and results in the exposure of spots 206 extending beyond outline 202, as seen, for example, at reference numeral 210, and the exposure of spots 208 not extending all of the way to outline 202, as seen, for example, at reference numeral 212. This results in a sub-optimal overall exposure, which has a fuzzy edge.

Reference is now made to FIG. 3B, which illustrates direct writing in accordance with an embodiment of the present invention, wherein the desired dimensions of an object to be written, such as a pad 220, as dictated by CAM data, are indicated by an outline designated by reference numeral 222.

In accordance with an embodiment of the present invention, and as distinct from the prior art practice illustrated in FIG. 3A, composite spots including first and second mutually concentric spots, which are simultaneously written using light at multiple wavelengths/intensities, are not employed.

In accordance with an embodiment of the present invention, an object, such as pad 220, is written by exposing the substrate 166 to light at a multiplicity of partially mutually overlapping spots, wherein spots written with light at different wavelengths/intensities are normally not mutually concentric and are not written simultaneously.

In accordance with an embodiment of the present invention and as shown in FIG. 3B, the substrate is exposed, with light at a first wavelength/intensity (W/I), at a multiplicity of partially mutually overlapping spots 226, each having a first spot size, as measured by a first spot diameter, and together forming a first pattern. The centers of all of the spots 226 lie along a first spot center outline 227, which is normally interior of and spaced from the outline 222 by a separation S1. The substrate is also exposed, with light at a second wavelength/intensity (W/I), at a multiplicity of partially mutually overlapping spots 228, each having a second spot size, as measured by a second spot diameter, and together forming a second pattern. The centers of all of the spots 228 lie along a second spot center outline 229, which is normally interior of and spaced from the outline 222 by a separation S2, different from S1. Additional patterns (not shown) may be written at other wavelengths/intensities (W/I).

As in FIG. 3A, for the sake of clarity and simplicity, the first wavelength is selected, for example, to be 365 nm, the first intensity is selected to be between 1 W and 20 W per frame, the spot size of spot 226, as measured by the diameter of spot 226, is selected, for example, to be 30 microns, the second wavelength is selected, for example, to be 385 nm, the second intensity is selected to be between 1 W to 20 W per frame and the spot size of spot 228, as measured by the diameter of spot 228, is selected, for example, to be 20 microns. As distinct from FIG. 3A, the object, here pad 220, is written by exposing a multiplicity of partially overlapping spots 226 and 228, typically none of which are mutually concentric. Typically an object, such as pad 220, having a typical dimension ranging from approximately 30 microns to several millimeters, is written by exposing mutually overlapping spots 226 and 228, wherein adjacent spots have a degree of overlap of between 0% and 100%.

It is appreciated that normally more than two different wavelengths/intensities of light are employed and the spots of each different wavelength/intensity are written at different times and have their centers arranged along a correspondingly different spot center outline, which is normally interior of and spaced from the outline 222 by a correspondingly different separation S but may, due to production chemistry, be defined partially externally to outline 222.

It is appreciated that while, in the illustrated example, spots 226 and 228 are circular shaped, spots 226 and 228 may be other than circular shaped, such as, for example, square, hexagonal or any other suitable shape.

It is further appreciated that any of the wavelengths, described herein as being a single discrete wavelength, may be either a single discrete wavelength, such as 365 nm or 385 nm, or a range of wavelengths, such as 365-405 nm or another suitable wavelength range. It is further appreciated that any of the intensities, described herein as being a single discrete intensity, may be either a single discrete intensity, such as 5 W/frame for 385 nm or 10 w/frame for 405 nm, or a range of intensities, such as 2 W/5 W/10 W per frame for respective wavelengths of 365 nm/385 nm/405 nm or 10 W/10 W/10 W per frame for respective wavelengths of 365 nm/385 nm/405 nm or any other suitable intensity range.

Reference is now made to FIG. 3C, which illustrates direct writing in accordance with another embodiment of the present invention, wherein the desired dimensions of an object to be written, such as a pad 230, as dictated by CAM data, are indicated by an outline designated by reference numeral 232. In accordance with an embodiment of the present invention, and as distinct from the prior art practice illustrated in FIG. 3A, composite spots including first and second mutually concentric spots, which are simultaneously written using light at multiple wavelengths and/or multiple intensities, are not employed.

In the embodiment shown in FIG. 3C, the substrate is exposed with light at a first wavelength/intensity (W/I) at a multiplicity of partially mutually overlapping spots 236, each having a first spot size, as measured by a first spot diameter, and together forming a first pattern. The centers of all of the spots 236 lie along a first spot center outline 237 which is normally interior of and spaced from the outline 232 by a separation S1. The substrate is also exposed with light at a second wavelength/intensity (W/I) at a multiplicity of partially mutually overlapping spots 238, each having a second spot size, as measured by a second spot diameter, and together forming a second pattern. The centers of all of the spots 238 lie along a second spot center outline 239, which is normally interior of and spaced from the outline 222 by a separation S2, different from S1. Additionally, as seen in FIG. 3C, alphanumeric characters 240, such as appear in legends 242, are written in a collection of spots 244 with light at one or more wavelengths/intensities (W/I) which may be different from the wavelengths/intensities (W/I) used for writing objects such as pads 230. The centers of all of spots 244, written at a third wavelength/intensity (W/I), all lie along a single spot center outline 246.

It is appreciated that the term legend, as used in this description, refers to any alphanumeric or text characters.

As in FIG. 3A, for the sake of clarity and simplicity, the first wavelength is selected, for example, to be 365 nm, the first intensity is selected to be between 1 W and 20 W per frame, the spot size of spot 236, as measured by the diameter of spot 236, is selected, for example, to be 30 microns, the second wavelength is selected, for example, to be 385 nm, the second intensity is selected to be between 1 W to 20 W per frame and the spot size of spot 238, as measured by the diameter of spot 238, is selected, for example, to be 20 microns. As distinct from FIG. 3A, the object, here pad 230, is written by exposing a multiplicity of partially overlapping spots 236 and 238, typically none of which are mutually concentric. Typically an object, such as pad 230, having a typical dimension ranging from approximately 30 microns to several millimeters, is written by exposing mutually overlapping spots 236 and 238, wherein adjacent spots have a degree of overlap of between 0% and 100%.

In the embodiment shown in FIG. 3C, the third wavelength, typically 405 nm, and the third intensity, typically between 1 W and 20 W per frame, is employed for writing alphanumeric characters 240 and spots 244, having a spot size, as measured by a diameter thereof, of 10 microns, are employed.

It is appreciated that optical writing heads 180 of maskless lithography apparatus 100 can be capable of writing patterns, which may be part of a device or a legend, with a legend and text resolution of less than 300 microns. In an instance, optical writing heads 180 are capable of writing with a legend and text resolution of less than 200 microns. In another instance, optical writing heads 180 are capable of writing with a legend and text resolution of less than 100 microns. In another instance, optical writing heads 180 are capable of writing with a legend and text resolution of less than 50 microns.

It is also appreciated that while, in the illustrated examples shown in FIGS. 3B and 3C, only a generally linear connection portion and an outline of pad 220 and pad 230 is illustrated as being written by optical writing heads 180, optical writing heads 180 may be operative to write not only the outline of a pad, such as pad 220 or pad 230, but the entire interior portion of a pad, such as pad 220 or pad 230, as well as one or more connection portions thereof.

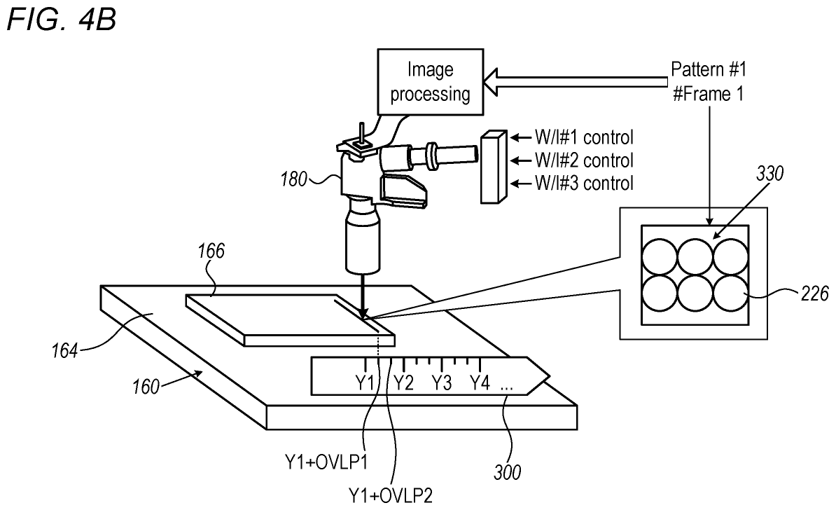

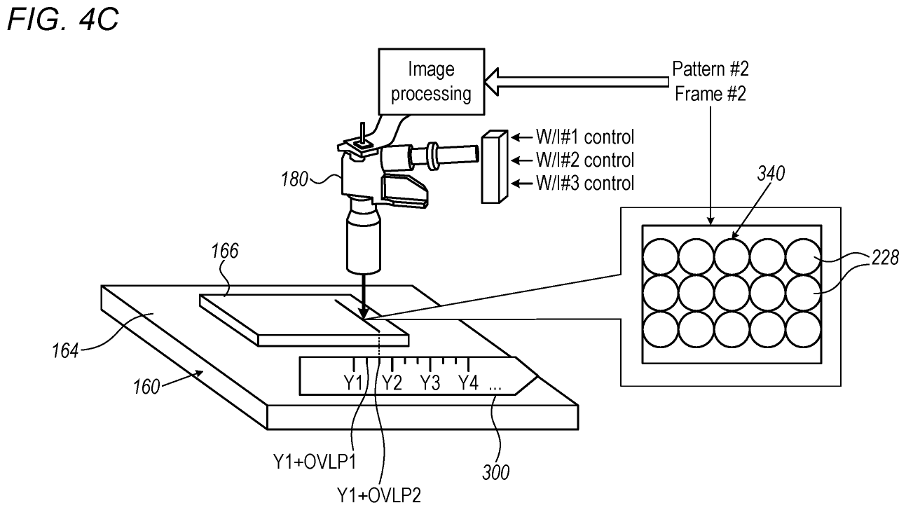

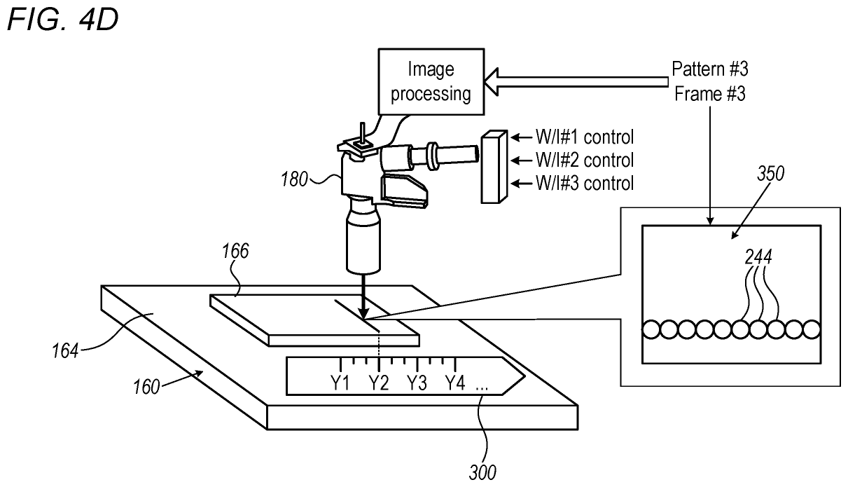

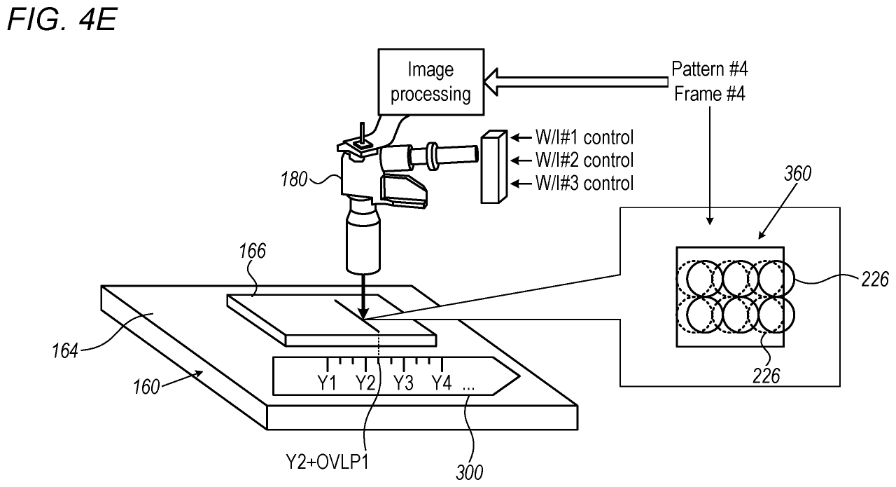

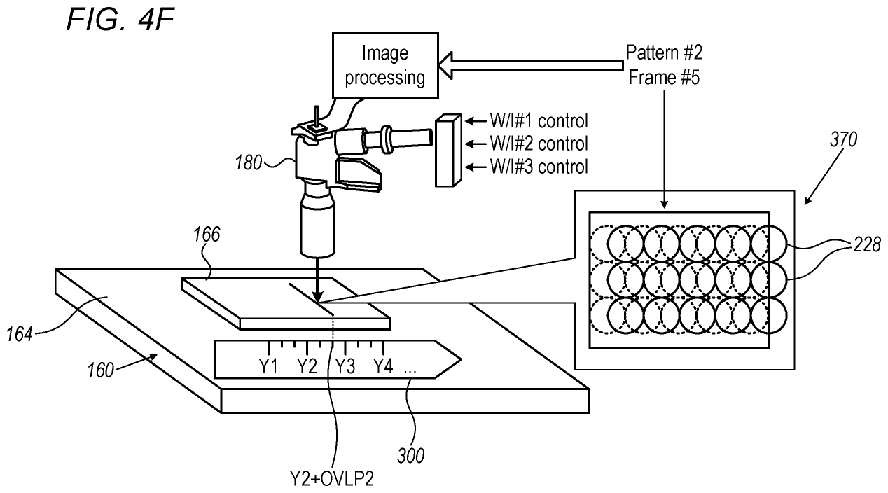

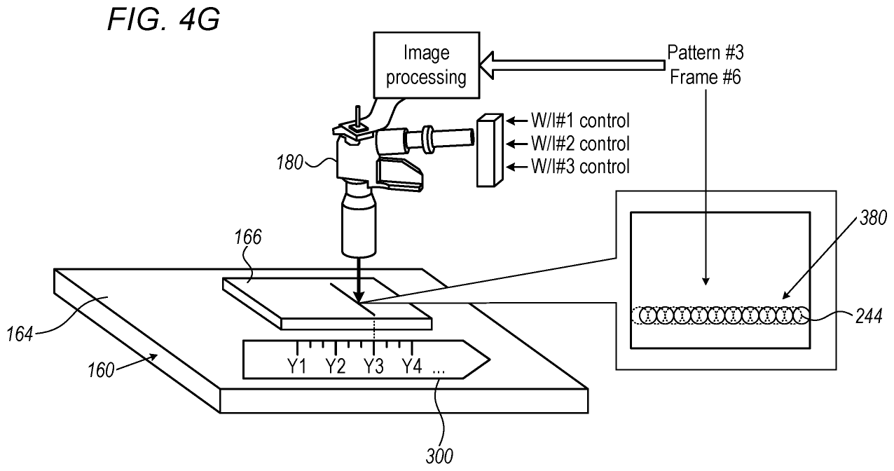

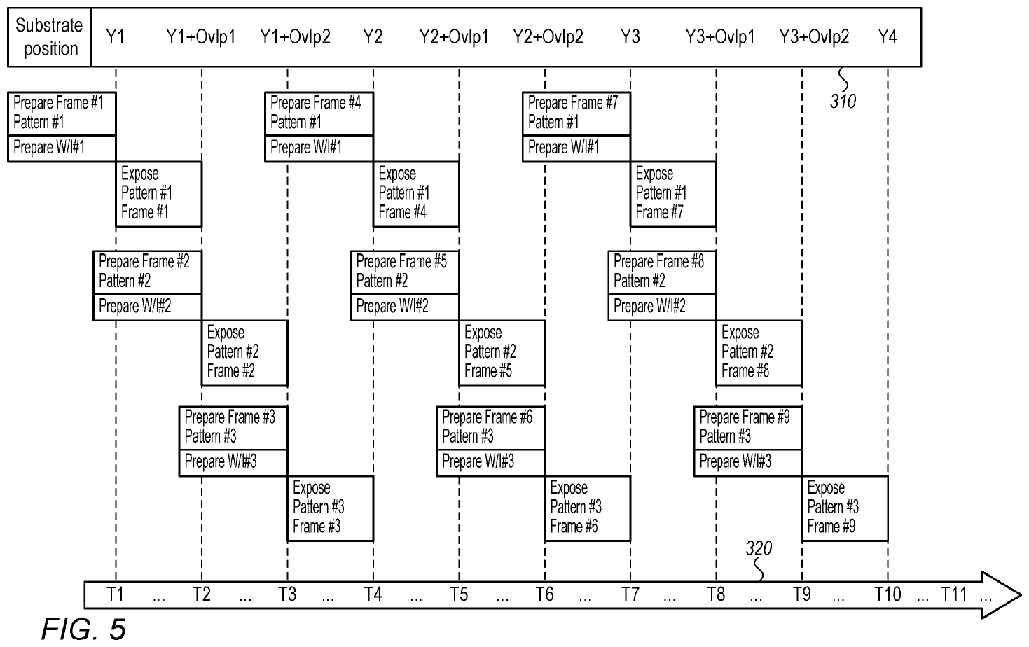

Reference is now made to FIGS. 4A, 4B, 4C, 4D, 4E, 4F and 4G, which are simplified schematic illustrations of multiple stages of direct writing of three different patterns, each using a different wavelength. The explanation which follows also makes reference to FIG. 5, which is a simplified schematic timing and displacement diagram illustrating typical writing operation of an optical writing head, sequentially writing different patterns, each at a different wavelength, onto a moving substrate in accordance with an embodiment of the present invention.

It is appreciated that, for simplicity of explanation and illustration, the description which follows illustrates the use of a single writing head 180, although it is anticipated that multiple writing heads 180 will be employed.

As noted above, during operation, substrate 166 is in uniform linear motion relative to writing head 180 typically in a Y-axis direction indicated by an arrow 300, in FIGS. 4A-4G. Accordingly, the position of that location on the substrate 166 which is currently being written by writing head 180 changes linearly over time. The locations on the substrate 166 along the Y-axis which are currently being written are designated on arrow 300 by indicia Y1, Y2, Y3 . . . as well as intermediate indicia, such as Y1+OVLP1 and Y1+OVLP2. Turning to FIG. 5, there appears a scale 310, which bears the same indicia Y1, Y2, Y3 as well as intermediate indicia such as Y1+OVLP1 and Y1+OVLP1. FIG. 5 also includes a time line 320, which includes time indicia T1, T2, T3 . . . corresponding to the various positions of the substrate 166 relative to the writing head 180 indicated in scale 310.

For example, referring to FIG. 3B, where the largest dimension of an object such as pad 220 along the Y-axis typically is approximately 100 microns, the separation distance along the Y-axis between respective adjacent substrate positions Y1, Y2, Y3 . . . typically is 3 microns and the separation distance along the Y-axis between respective adjacent substrate positions, such as Y1, Y1+OVLP1, Y1+OVLP2 and Y2, typically is 1 micron. The time separation between adjacent time indicia T1, T2, T3 . . . is typically 50 microseconds.

FIG. 4A illustrates the mutual positions of the substrate 166 and the writing head 180 along the Y-axis at an arbitrary starting position, here designated Y1, at time T1. As noted in FIG. 5, prior to time T1, pattern writing instructions for writing a first frame of a first pattern, designated pattern 1, at a first wavelength/intensity, designated W/I #1, typically 365 nm at between 1 W and 20 W per frame, are prepared and provided to writing head 180.

Preparation of the pattern writing instructions for each frame of each pattern and writing each frame of each pattern typically include the following steps, here described with reference to the first frame of pattern 1:
Obtaining CAM data from lithography computer 184 (FIG. 1);
Obtaining specific pattern writing instructions to prepare a full exposure pattern for pattern 1 from the pattern 1 generator 194 (FIG. 1);
Preparing sequential frames for the pattern 1 by employing frame and wavelength/intensity generator 196 (FIG. 1) and step/frame generator 198 (FIG. 1);
Correcting the frames by spatial transformations;
Generating the first frame of pattern 1 to be exposed when the substrate 166 is at position Y1;
Exposing the first frame of pattern 1 on the substrate 166 between positions Y1 and Y1+OVLP1 at W/I #1 and at a power level as established by power controller 195 (FIG. 1) forming part of power source driver 192 (FIG. 1).

Frame 1, being the first frame of pattern 1, is written between times T1 and T2. The resulting written pattern is schematically shown and designated by reference numeral 330 in FIG. 4B, which also illustrates the mutual positions of the substrate 166 and the writing head 180 along the Y-axis at a position, designated Y1+OVLP1, at time T2. Considering FIG. 3B and pattern 330 of FIG. 4B, it is appreciated that frame 1, which is the first frame of pattern 1, may include ½ million to 10 million spots 226, of which only 12 are illustrated in FIG. 3B and only 6 of which are illustrated in FIG. 4B.

FIG. 4C illustrates the mutual positions of the substrate 166 and the writing head 180 along the Y-axis at a position, designated Y1+OVLP2, at time T3. As noted in FIG. 5, prior to time T2, pattern writing instructions for writing frame 2, which is a first frame of a second pattern, designated pattern 2, at a second wavelength/intensity, designated W/I #2, typically 385 nm at between 1 W and 20 W per frame, are prepared and provided to writing head 180.

Preparation of the pattern writing instructions for frame 2 typically includes the above-listed steps, there described with reference to frame 1 of pattern 1.

Frame 2, being a first frame of pattern 2, is written between times T2 and T3. The resulting written pattern is schematically shown and designated by reference numeral 340 in FIG. 4C, which also illustrates the mutual positions of the substrate 166 and the writing head 180 along the Y-axis at a position, designated Y1+OVLP2, at time T3. Considering FIG. 3B and pattern 340 of FIG. 4C, it is appreciated that frame 2, which is the first frame of pattern 2, may include ½ million to 10 million spots 228, of which only 17 are illustrated in FIG. 3B and only 15 of which are illustrated in FIG. 4C.

FIG. 4D illustrates the mutual positions of the substrate 166 and the writing head 180 along the Y-axis at a position, designated Y2, at time T4. As noted in FIG. 5, prior to time T3, pattern writing instructions for writing frame 3, which is a first frame of a third pattern, designated pattern 3, at a third wavelength/intensity, designated W/I #3, typically 405 nm at between 1 W and 20 W per frame, are prepared and provided to writing head 180.

Preparation of the pattern writing instructions for frame 3 typically includes the above-listed steps, there described with reference to frame 1 of pattern 1.

Frame 3, being a first frame of pattern 3, is written between times T3 and T4. The resulting written pattern is schematically shown and designated by reference numeral 350 in FIG. 4D, which also illustrates the mutual positions of the substrate 166 and the writing head 180 along the Y-axis at a position, designated Y2, at time T4. Considering FIG. 3C and pattern 350 of FIG. 4D, it is appreciated that frame 3, which is the first frame of pattern 3, may include ½ million to 10 million spots 244, of which only 7 are illustrated in FIG. 3C and only 10 of which are illustrated in FIG. 4C.

FIG. 4E illustrates the mutual positions of the substrate 166 and the writing head 180 along the Y-axis at a position, designated Y2+OVLP1, at time T5. As noted in FIG. 5, prior to time T4, pattern writing instructions for writing frame 4, which is a second frame of pattern 1 at W/I #1, typically 365 nm at between 1 W and 20 W per frame, are prepared and provided to writing head 180.

Preparation of the pattern writing instructions for frame 4 typically includes the above-listed steps, there described with reference to frame 1 of pattern 1.

Frame 4, being a second frame of pattern 1, is written between times T4 and T5. The resulting written pattern is schematically shown and designated by reference numeral 360 in FIG. 4E, which also illustrates the mutual positions of the substrate 166 and the writing head 180 along the Y-axis at a position, designated Y2+OVLP1, at time T5. Considering FIG. 3B and pattern 360 of FIG. 4E, it is appreciated that frame 4, which is the second frame of pattern 1, may include ½ million to 10 million spots 226, of which only 12 are illustrated in FIG. 3B and only 6 of which are illustrated in FIG. 4E. It is noted that in FIG. 4E, spots 226 written in frame 4 (shown in solid lines) are written in partially overlapping relationship to spots 226 (shown in dashed lines) earlier written in frame 1. The offset along the Y-axis between spots 226 written in frame 4 (shown in solid lines) and spots 226 (shown in dashed lines) earlier written in frame 1 is equal to distance between substrate positions Y1+OVLP1 and Y2+OVLP1.

FIG. 4F illustrates the mutual positions of the substrate 166 and the writing head 180 along the Y-axis at a position, designated Y2+OVLP2, at time T6. As noted in FIG. 5, prior to time T5, pattern writing instructions for writing frame 5, which is a second frame of pattern 2, at W/I #2, typically 385 nm at between 1 W and 20 W per frame, are prepared and provided to writing head 180.

Preparation of the pattern writing instructions for frame 5 typically includes the above-listed steps, there described with reference to frame 1 of pattern 1.

Frame 5, being a second frame of pattern 2, is written between times T5 and T6. The resulting written pattern is schematically shown and designated by reference numeral 370 in FIG. 4F, which also illustrates the mutual positions of the substrate 166 and the writing head 180 along the Y-axis at a position, designated Y2+OVLP2, at time T6. Considering FIG. 3B and pattern 370 of FIG. 4F, it is appreciated that frame 5, which is the second frame of pattern 2, may include ½ million to 10 million spots 228, of which only 17 are illustrated in FIG. 3B and only 15 of which are illustrated in FIG. 4F. It is noted that in FIG. 4F, spots 228 written in frame 5 (shown in solid lines) are written in partially overlapping relationship to spots 228 (shown in dashed lines) earlier written in frame 2. The offset along the Y-axis between spots 228 written in frame 5 (shown in solid lines) and spots 228 (shown in dashed lines) earlier written in frame 2 is equal to distance between substrate positions Y1+OVLP2 and Y2+OVLP2.

FIG. 4G illustrates the mutual positions of the substrate 166 and the writing head 180 along the Y-axis at a position, designated Y3 at time T7. As noted in FIG. 5, prior to time T6, pattern writing instructions for writing frame 6, which is a second frame of pattern 3 at W/I #3, typically 405 nm at between 1 W and 20 W per frame, are prepared and provided to writing head 180.

Preparation of the pattern writing instructions for frame 6 typically includes the above-listed steps, there described with reference to frame 1 of pattern 1.

Frame 6, being a second frame of pattern 3, is written between times T6 and T7. The resulting written pattern is schematically shown and designated by reference numeral 380 in FIG. 4G, which also illustrates the mutual positions of the substrate 166 and the writing head 180 along the Y-axis at a position, designated Y3, at time T7. Considering FIG. 3B and pattern 380 of FIG. 4G, it is appreciated that frame 6, which is the second frame of pattern 3, may include ½ million to 10 million spots 244, of which only 7 are illustrated in FIG. 3C and only 10 of which are illustrated in FIG. 4G. It is noted that in FIG. 4G, spots 244 written in frame 6 (shown in solid lines) are written in partially overlapping relationship to spots 244 (shown in dashed lines) earlier written in frame 3. The offset along the Y-axis between spots 244 written in frame 6 (shown in solid lines) and spots 244 (shown in dashed lines) earlier written in frame 3 is equal to distance between substrate positions Y2 and Y3.

The mutual positions of the substrate 166 and the writing head 180 along the Y-axis at a position, designated Y3+OVLP1, at time T8 are not illustrated, since they cannot be seen clearly. As noted in FIG. 5, prior to time T7, pattern writing instructions for writing frame 7, which is a third frame of pattern 1 at W/I #1, are prepared and provided to writing head 180.

Preparation of the pattern writing instructions for frame 7 typically includes the above-listed steps, there described with reference to frame 1 of pattern 1.

Frame 7, being a third frame of pattern 1, is written between times T7 and T8. The resulting written pattern and the mutual positions of the substrate 166 and the writing head 180 along the Y-axis at a position, designated Y3+OVLP1, at time T8 are not illustrated. It is appreciated that frame 7, which is the third frame of pattern 1, may include ½ million to 10 million spots 226.

It is appreciated that spots 226 written in frame 7 are written in partially overlapping relationship to spots 226 earlier written in frame 4 and that spots 226 written in frame 4 are written in partially overlapping relationship to spots 226 earlier written in frame 1.

The offset along the Y-axis between spots 226 written in frame 7 and spots 226 earlier written in frame 4 is equal to distance between substrate positions Y2+OVLP1 and Y3+OVLP1. The offset along the Y-axis between spots 226 written in frame 4 and spots 226 earlier written in frame 1 is equal to distance between substrate positions Y1+OVLP1 and Y2+OVLP1.

The mutual positions of the substrate 166 and the writing head 180 along the Y-axis at a position, designated Y3+OVLP2 at time T9 are also not illustrated due to size considerations. As noted in FIG. 5, prior to time T8, pattern writing instructions for writing frame 8, which is a third frame of pattern 2, at W/I #2, are prepared and provided to writing head 180.

Preparation of the pattern writing instructions for frame 8 typically includes the above-listed steps, there described with reference to frame 1 of pattern 1.

Frame 8, being a third frame of pattern 2, is written between times T8 and T9. The resulting written pattern and the mutual positions of the substrate 166 and the writing head 180 along the Y-axis at a position, designated Y3+OVLP2, at time T9 are not illustrated. It is appreciated that frame 8, which is the third frame of pattern 2, may include ½ million to 10 million spots 228.

It is noted that spots 228 written in frame 8 are written in partially overlapping relationship to spots 228 earlier written in frame 5 and spots 228 written in frame 5 are written in partially overlapping relationship to spots 228 earlier written in frame 2.

The offset along the Y-axis between spots 228 written in frame 8 and spots 228 earlier written in frame 5 is equal to the distance between substrate positions Y2+OVLP2 and Y3+OVLP2. The offset along the Y-axis between spots 228 written in frame 5 and spots 228 earlier written in frame 2 is equal to distance between substrate positions Y1+OVLP2 and Y2+OVLP2.

The mutual positions of the substrate 166 and the writing head 180 along the Y-axis at a position, designated Y4, at time T10 are not illustrated due to size considerations. As noted in FIG. 5, prior to time T9, pattern writing instructions for writing frame 9, which is a third frame of pattern 3, at W/I #3, are prepared and provided to writing head 180.

Preparation of the pattern writing instructions for frame 9 typically includes the above-listed steps, there described with reference to frame 1 of pattern 1.

Frame 9, being a third frame of pattern 3, is written between times T9 and T10. The resulting written pattern and the mutual positions of the substrate 166 and the writing head 180 along the Y-axis at a position, designated Y4, at time T10 are not illustrated. It is appreciated that frame 9, which is the third frame of pattern 3, may include ½ million to 10 million spots 244.

It is noted that spots 244 written in frame 9 are written in partially overlapping relationship to spots 244 earlier written in frame 6 and spots 244 written in frame 6 are written in partially overlapping relationship to spots 244 earlier written in frame 3.

The offset along the Y-axis between spots 244 written in frame 9 and spots 244 earlier written in frame 6 is equal to distance between substrate positions Y3 and Y4. The offset along the Y-axis between spots 244 written in frame 6 and spots 226 earlier written in frame 3 is equal to distance between substrate positions Y2 and Y3.

It is appreciated that the foregoing description referring to FIGS. 4A-4F and FIG. 5 is applicable to exposing a multiplicity of subsequent frames, which may be of the order of several thousands to millions of frames per substrate, depending on resolution and substrate dimensions.

It is further appreciated that not all patterns must be written in each sequence of frames and that the patterns need not be written in any given or fixed order in sequential frames.

While the above embodiments describe forming a patterned object on a substrate, optical writing controller 178 may be operative to cause optical writing heads 180 to write a legend on soldermask.

Optical writing controller 178 may be operative to cause optical writing heads 180 to sequentially write a plurality of different patterns in a selectable sequence. Additionally or alternatively, optical writing controller 178 may be operative to cause optical writing heads 180 to sequentially write a plurality of different patterns at different intensities.

In a further embodiment, optical writing controller 178 may be operative to cause optical writing heads 180 to write a pattern, which may be a legend, at a size, intensity and soldermask legend hue which is invisible to the unaided human eye.

It is appreciated that optical writing controller 178 can be operative to cause optical writing heads 180 to write a legend with a legend to soldermask portion accuracy of less than 5 microns. In an instance, the legend to soldermask portion accuracy is less than 1 micron. In another instance, the legend to soldermask portion accuracy is less than 0.5 micron. In another instance, the legend to soldermask portion accuracy is less than 0.1 micron.

It is appreciated that optical writing controller 178 can be operative to cause optical writing heads 180 to write a legend with a spot size of less than 30 microns. In an instance, the spot size of less than 20 microns. In another instance, the spot size is less than 10 microns. In another instance, the spot size is less than 5 microns.

It is appreciated that while the method described hereinabove is described in reference to the maskless lithography apparatus described hereinabove, the method may be utilized with any lithography system.

It will be appreciated by persons skilled in the art that the present invention is not limited to what has been particularly shown and described hereinabove. Rather, the scope of the present invention includes both combinations and sub-combinations of the features shown and described hereinabove as well as modifications thereof, which are not in the prior art.

1. A maskless lithography apparatus comprising:
a chassis supporting a substrate onto which it is desired to write;
an optical writing head, said optical writing head being selectably operable at multiple ones of at least one of a plurality of at least partially different wavelength ranges and a plurality of at least partially different intensity ranges;
a displacement subsystem for providing desired relative displacement between said substrate and said optical writing head; and
a writing controller operative to cause said optical writing head to sequentially write a plurality of different patterns at correspondingly different ones of said multiple ones of at least one of said plurality of at least partially different wavelength ranges and said plurality of at least partially different intensity ranges.

2.-3. (canceled)

4. The maskless lithography apparatus according to claim 1, wherein said writing controller is operative to cause said optical writing head to sequentially write each of said plurality of different patterns at correspondingly said at least partially different wavelength, and/or said at least partially different intensity ranges by writing mutually partially overlapping spots of different spot sizes for each of said plurality of different patterns using light at correspondingly different ones of said at least partially different wavelength, and/or said at least partially different intensity ranges.

5. The maskless lithography apparatus according to claim 1, wherein said mutually partially overlapping spots of different spot sizes are non-concentric.

6. The maskless lithography apparatus according to claim 1, and wherein at least one of said plurality of different patterns defines an alphanumeric character.

7. The maskless lithography apparatus according to claim 1, wherein said writing controller is also operative to cause said optical writing head to write legends on soldermask.

8. The maskless lithography apparatus according to claim 1, wherein said writing controller is operative to cause said optical writing head to write each of said plurality of different patterns in a plurality of frames at a corresponding plurality of different times.

9. The maskless lithography apparatus according to claim 1, wherein said writing controller is operative to write each of said plurality of different patterns with a plurality of spots of a uniform size, the uniform size of the spots for each of said plurality of different patterns being different.

10. The maskless lithography apparatus according to claim 9, wherein said plurality of spots written for each of said plurality of different patterns are written at partially mutually overlapping locations on said substrate.

11. The maskless lithography apparatus according to claim 9, and wherein said plurality of spots written for each of said plurality of different patterns are each written at locations such that the centers of all of said plurality of spots forming a single pattern lie inside a single spot center outline.

12. The maskless lithography apparatus according to claim 11, wherein the single spot center outline of each pattern is arranged such that a corresponding spot of the plurality of spots does not extend beyond the design boundaries of an object to be written thereby.

13. A maskless lithography apparatus comprising:
a chassis supporting a substrate onto which it is desired to write;
an optical writing head, said optical writing head being selectably operable at multiple ones of at least one of a plurality of at least partially different wavelength ranges and a plurality of at least partially different intensity ranges;
a displacement subsystem for providing desired relative displacement between said substrate and said optical writing head; and
a writing controller operative to cause said optical writing head to write a plurality of different patterns at corresponding ones of said plurality of at least partially different wavelength ranges by writing partially mutually overlapping non-concentric spots at correspondingly different ones of said multiple ones of at least one of said plurality of at least partially different wavelength ranges and said plurality of at least partially different intensity ranges.

14.-20. (canceled)

21. A maskless lithography apparatus comprising:
a chassis supporting a substrate onto which it is desired to write;
an optical writing head, said optical writing head being selectably operable at multiple ones of a plurality of at least partially different wavelength ranges;
a displacement subsystem for providing desired relative displacement between said substrate and said optical writing head; and
a writing controller operative to cause said optical writing head to sequentially write a plurality of different patterns at corresponding ones of said plurality of at least partially different wavelength ranges, said plurality of different patterns including patterns for electrical circuit features and alphanumeric characters.

22.-31. (canceled)

32. The maskless lithography apparatus according to claim 21, wherein said optical writing head operates at a plurality of at least partially different wavelength ranges and at a plurality of at least partially different intensity ranges and said writing controller is operative to cause said optical writing head to sequentially write a plurality of different patterns at correspondingly different ones of said plurality of at least partially different wavelength ranges and at a plurality of at least partially different intensity ranges.

33. The maskless lithography apparatus according to claim 21, wherein said optical writing head is capable of writing with a legend and a text resolution of less than 300 microns.

34.-36. (canceled)

37. The maskless lithography apparatus according to claim 21, wherein said writing controller is operative to cause said optical writing head to sequentially write a plurality of different patterns in a selectable sequence.

38. The maskless lithography apparatus according to claim 21, wherein said writing controller is operative to cause said optical writing head to sequentially write a plurality of different patterns at different intensities.

39. The maskless lithography apparatus according to claim 21, wherein said writing controller is operative to cause said optical writing head to write a pattern and/or a legend at a size, an intensity and a soldermask legend hue which is invisible to an unaided human eye.

40. (canceled)

41. The maskless lithography apparatus according to claim 21, wherein said writing controller is operative to cause said optical writing head to write a legend with a legend to soldermask accuracy of less than 5 microns.

42.-44. (canceled)

45. The maskless lithography apparatus according to claim 21, wherein said writing controller is operative to cause said optical writing head to write a legend at a spot size of less than 30 microns.

46.-99. (canceled)
